(19) United States
(12) Patent Application Publication
(10) Pub. No.: US 2015/0187887 A1
(43) Pub. Date: Jul. 2, 2015

(54) III NITRIDE SEMICONDUCTOR DEVICE AND METHOD OF MANUFACTURING THE SAME

(71) Applicants: Meoung Whan Cho, Yongin-City (KR); Seog Woo Lee, Yongin-City (KR); Pil Guk Jang, Yongin-City (KR); Hoe Young Yang, Yongin-City (KR); Jin Hee Kim, Yongin-City (KR); Ho Kyun Rho, Yongin-City (KR); Se Young Moon, Yongin-City (KR); Ryuichi Toba, Akita-shi (JP); Yoshitaka Kadowaki, Akita-shi (JP)

(72) Inventors: Meoung Whan Cho, Yongin-City (KR); Seog Woo Lee, Yongin-City (KR); Pil Guk Jang, Yongin-City (KR); Hoe Young Yang, Yongin-City (KR); Jin Hee Kim, Yongin-City (KR); Ho Kyun Rho, Yongin-City (KR); Se Young Moon, Yongin-City (KR); Ryuichi Toba, Akita-shi (JP); Yoshitaka Kadowaki, Akita-shi (JP)

(73) Assignees: DOWA ELECTRONICS MATERIALS CO., LTD., Tokyo (JP); BBSA LIMITED, Hong Kong (CN)

(21) Appl. No.: 14/412,916

(22) PCT Filed: Jul. 4, 2012
(86) PCT No.: PCT/JP2012/004344

§ 371 Date: Feb. 10, 2015

(51) Int. Cl. H01L 29/20; H01L 29/45; H01L 21/308; H01L 21/02; H01L 21/28

(52) U.S. Cl. CPC H01L 29/2003; H01L 21/0254; H01L 21/28132; H01L 21/3086; H01L 21/28158; H01L 29/452

(57) ABSTRACT

Provided is a III nitride semiconductor device higher heat dissipation performance, and a method of manufacturing a III nitride semiconductor device which makes it possible to fabricate such a III nitride semiconductor device at higher yield. In a method of a III nitride semiconductor device, a semiconductor structure obtained by sequentially stacking an n-layer, an active layer, and a p-layer is formed on a growth substrate; a support body including a first support electrically connected to an n-layer to serve as an n-side electrode, a second support electrically connected to a p-layer to serve as a p-side electrode, and structures made of an insulator for insulation between first and second supports is formed on the p-layer side of the semiconductor structure; and the growth substrate is separated using a lift-off process. The first support and the second support are grown by plating.

### TECHNICAL FIELD

The present invention relates to a III nitride semiconductor device and a method of manufacturing the same.

### BACKGROUND ART

Examples of semiconductor devices include various devices, including field effect transistors (FETs), light emitting diodes (LEDs), and the like. For those semiconductor devices, for example, Group III-V semiconductors made of compounds of Group III and Group V elements are used.

A Group III nitride semiconductor using Al, Ga, In, or the like as a Group III element and using N as a Group V element has a high melting point and a high dissociation pressure of nitrogen, which makes it difficult to perform bulk single crystal growth. Further, conductive single crystal substrates having large diameter are not available at low cost. Accordingly, such a semiconductor is typically formed on a sapphire substrate.

However, since a sapphire substrate is insulative, current does not flow. Therefore, in recent years, methods of fabricating a vertical structure LED chip or the like, in which III nitride semiconductor layers are supported by a support have been studied, in which method the III nitride semiconductor layers including a light emitting layer is formed on a growth substrate such as a sapphire substrate, and after the support is separately bonded onto the III nitride semiconductor layers, the sapphire substrate is separated (lifted off).

A structure shown in FIGS. 10(A) and 10(B) is known as an aspect of such an LED chip fabricated by the method. In a III nitride semiconductor LED chip 200 in FIGS. 10(A) and 10(B), a semiconductor structure 204 having an n-type III nitride semiconductor layer (n-layer) 201, a light emitting layer 202, and a p-type III nitride semiconductor layer (p-layer) 203 in this order has a structure supported by a submount substrate 210. There are provided n-side contact layers 205 on the n-layer 201 at the bottom of recessed portions penetrating the p-layer 203 and the light emitting layer 202, whereas there are provided p-side contact layers 206 on the p-layer 203. An insulating layer 207 for the insulation between the n-side contact layers 205 and the p-side contact layers 206 is provided therebetween. Both Au bumps 208A electrically connected to the n-side contact layers and Au bumps 208B electrically connected to the p-side contact layer extend from the same side of the semiconductor structure 204. The submount substrate 210 is provided with wires for n-layer 210A and wires for p-layer 210B. The Au bumps 208A and the wires for n-layer 210A are joined, whereas the Au bumps 208B and the wires for p-layer 210B are joined. The spaces between the Au bumps 208A and 208B is filled with under-filling 209 made of an epoxy resin. The back surface of the support 210 is provided with solders 211 electrically connected to the wires for n-layer 210A and the wires for p-layer 210B. The LED chip 200 is mounted on a package substrate or a printed wiring board (not shown) or the like via the solders 211.

Such an LED chip 200 is manufactured for example by a lift-off process described below. First, the n-layer 201, the light emitting layer 202, and the p-layer 203 are epitaxially grown on a growth substrate such as a sapphire substrate (not shown). After that, using a known film formation method such as etching, vapor deposition, plating, or patterning, the n-side contact layers 205, the p-side contact layers 206, the insulating layer 207, and the Au bumps 208A and 208B are formed. The growth substrate is then aligned to and pressed against the support substrate 210 such that the Au bumps 208A and the wires for n-layer 210A are joined, and the Au bumps 208B and the wires for p-layer 210B are joined. Subsequently, the under-filling 209 is injected and the growth substrate is finally lifted off to obtain the LED chip 200.

Such a manufacturing method is disclosed in JP 2010-533374 A (PTL1) and JP 2006-128710 A (PTL 2). PTL 1 also describes that the under-filling 209 is formed before joining the Au bumps 208A and 208B to the support substrate 210.

### CITATION LIST

### Patent Literature

PTL 1: JP 2010-533374 A

PTL 2: JP 2006-128710 A

### SUMMARY OF INVENTION

### Technical Problem

However, in the manufacturing method as described above, it is difficult to control the mutual position of Au bumps with respect to wires of the support substrate and control the pressing force of the Au bumps against the support substrate, so that it is difficult to perfectly align the Au bumps with the wires of the support substrate. Further, once the Au bumps are brought in contact with the support substrate, if the Au bumps are misaligned with the wires of the support substrate, reworking is impossible. The inventors of the present invention focused on the problem in that due to those difficulties, sufficient yield cannot be obtained by the above manufacturing method. Further, they focused on that the LED chip as described above uses a large amount of under-filling between the Au bumps, which leads to impeded heat dissipation of the LED chip because the under-filling has significantly lower heat dissipation performance as compared with the Au bumps.

Thus, the inventors came to recognize that in manufacturing a III nitride semiconductor device in which a current path to an n-layer and a current path to a p-layer are secured on the same side of a semiconductor structure, by chemical lift-off process, it is important to solve the above problems for mass production and performance improvement of the III nitride semiconductor device.

In view of the above problems, it is therefore an object of the present invention to provide a III nitride semiconductor device having higher heat dissipation performance, and a method of manufacturing a III nitride semiconductor device, which makes it possible to fabricate such a III nitride semiconductor device at higher yield.

### Solution to Problem

In order to achieve the above object, the present invention primarily includes the following features.

(1) A method of manufacturing a III nitride semiconductor device, comprising:

a first step of forming semiconductor structures obtained by sequentially stacking a first conductivity type III nitride semiconductor layer, an active layer, and a second conductivity type III nitride semiconductor layer on a growth substrate;

a second step of partly exposing the first conductivity type III nitride semiconductor layer by partly removing the second conductivity-type III nitride semiconductor layer and the active layer;

a third step of forming first contact layers on exposed portions of the first conductivity type III nitride semiconductor layer and forming second contact layers on exposed portions of the second conductivity type III nitride semiconductor layer;

a fourth step of forming an insulating layer on the semiconductor structures, the first contact layers, and the second contact layers that are exposed, with part of the first contact layers and part of the second contact layers being exposed;

a fifth step of forming a first structure made of an insulator on part of the insulating layer across an exposed surface, thereby partitioning the exposed surface into a first exposed surface having the exposed portions of the first contact layers and a second exposed surface having the exposed portion of the second contact layer, by the first structure;

a sixth step of growing a plating layer from the first and second exposed surfaces, thereby forming a first support serving as a first electrode in contact with the exposed portions of the first contact layers on the first exposed surface, and forming a second support serving as a second electrode in contact with the exposed portion of the second contact layer on the second exposed surface; and

a seventh step of separating the growth substrate using a lift-off process, whereby a III nitride semiconductor device having the semiconductor structures supported by a support body including the first and second supports and the first structure is fabricated.

(2) The method of manufacturing a III nitride semiconductor device, according to (1) above, wherein in the second step, exposed portions of the first conductivity type III nitride semiconductor layer are formed at a plurality of positions in the semiconductor structure, and in the third step, the first contact layers are formed at a plurality of positions.
(3) The method of manufacturing a III nitride semiconductor device, according to (2) above, wherein the sixth step comprises:

a first plating step for forming a first layer of the first support on the first exposed surface and growing a first layer of the second support on the second exposed surface by plating;

a step of forming a second structure made of an insulator and coupled to the first structure, on the first layer of the first support; and

a second plating step for growing from the first layer of the first support and the first layer of the second support that are exposed, a second layer of the first support and a second layer of the second support, respectively by plating, wherein the top surface area of the first layer of the second support after the first plating step is larger than that of the second layer of the second support.

(4) A III nitride semiconductor device comprising:

semiconductor structures each having a first conductivity type III nitride semiconductor layer, an active layer, and a second conductivity-type III nitride semiconductor layer in this order;

a first contact layer provided on the first conductivity type III nitride semiconductor layer at the bottom of a recessed portion penetrating the second conductivity-type III nitride semiconductor layer and the active layer;

a second contact layer provided on the second conductivity type III nitride semiconductor layer;

an insulating layer for insulation between the first contact layer and the second contact layer, provided on part of the first contact layer, part of the second contact layer, and the semiconductor structure situated between the first contact layer and the second contact layer and;

a single first support partly in contact with the first contact layer to serve as a first electrode, a single second support partly in contact with the second contact layer to serve as a second electrode, and a structure made of an insulator located between the adjacent first and second supports on the insulating layer, wherein the first and second supports and the structure constitute a support body for supporting the semiconductor structure.

(5) The III nitride semiconductor device, according to (4) above, wherein the semiconductor structure has recessed portions at a plurality of positions, and the first contact layer is provided at a plurality of positions.
(6) The III nitride semiconductor device, according to (5) above, wherein the first and second supports each include a first layer provided on the insulating layer and a second layer provided on the first layer,

the structure includes a first structure situated between the first layers of the first and second supports, and a second structure coupled to the first structure and situated between the second layers of the first and second supports, and

the top surface area of the second layer of the second support is larger than that of the first layer of the second support.

### Advantageous Effect of Invention

The present invention can provide a III nitride semiconductor device having higher heat dissipation performance, and a method of manufacturing a III nitride semiconductor device, which makes it possible to fabricate such a III nitride semiconductor device at higher yield.

### BRIEF DESCRIPTION OF DRAWINGS

FIGS. 1(A) and 1(B) are schematic cross-sectional side views showing some of the steps of a method of manufacturing a III nitride semiconductor device 100 according to one embodiment of the present invention.

FIGS. 2(A) and 2(B) are schematic cross-sectional side views showing the steps following the step shown in FIG. 1(B).

FIGS. 3(A) and 3(B) are schematic cross-sectional side views showing the steps following the step shown in FIG. 2(B).

FIG. 4 is a schematic cross-sectional side view showing the step following the step shown in FIG. 3(B).

FIG. 5 is a schematic cross-sectional side view showing the step following the step shown in FIG. 4.

FIG. 6 is a schematic cross-sectional side view showing the step following the step shown in FIG. 5.

FIG. 7 is a schematic cross-sectional side view showing the step following the step shown in FIG. 6.

FIGS. 8(A) and 8(B) are schematic top views of FIG. 1(B) and FIG. 2(A), respectively.

FIGS. 9(A) and 9(B) are schematic top views of FIG. 2(B) and FIG. 3(B), respectively.

FIG. 10(A) is a schematic cross-sectional side view of a conventional III nitride semiconductor LED chip, whereas FIG. 10(B) is a cross-sectional view along line in FIG. 10(A).

### DESCRIPTION OF EMBODIMENTS

Embodiments of the present invention will now be described with reference to the drawings.

### (Method of Manufacturing III Nitride Semiconductor Device 100)

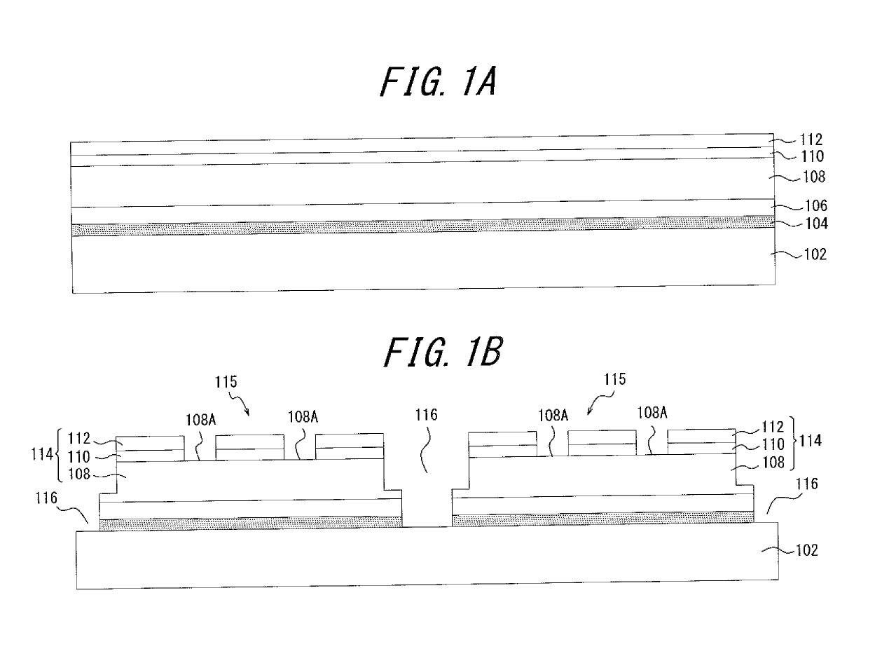

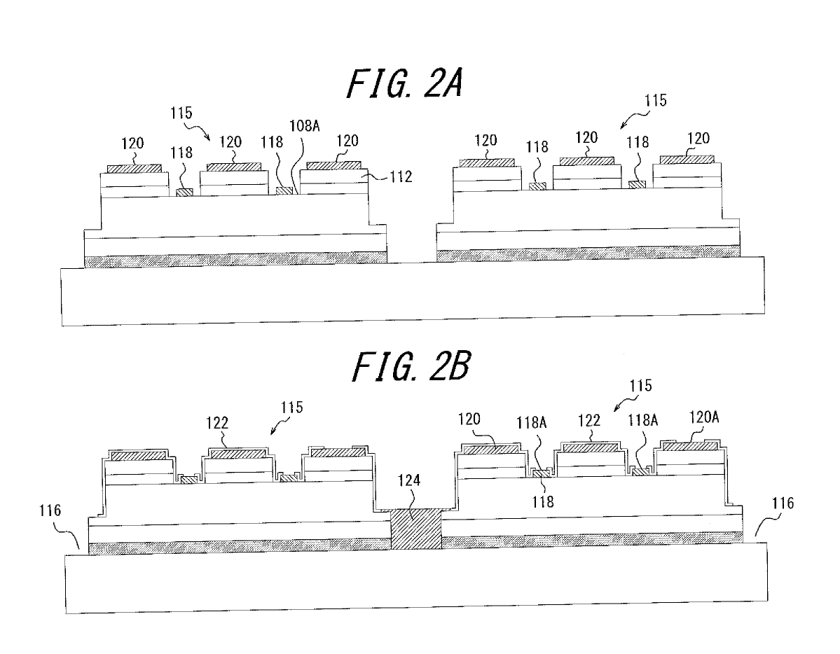

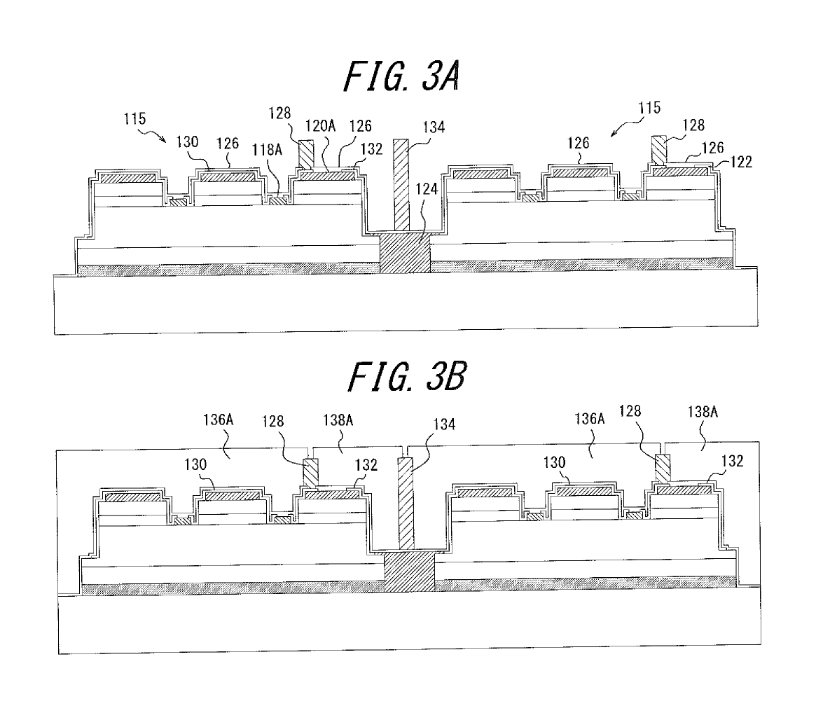

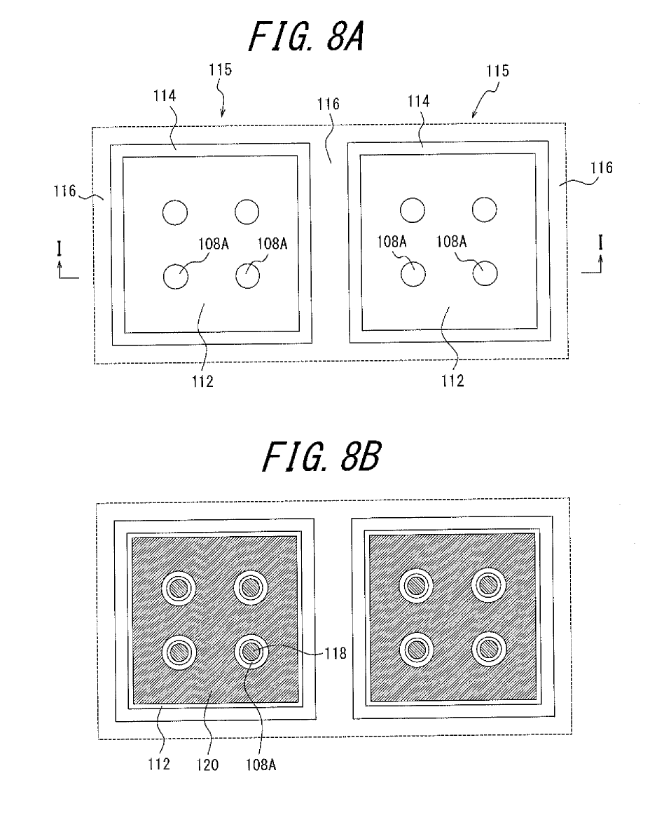

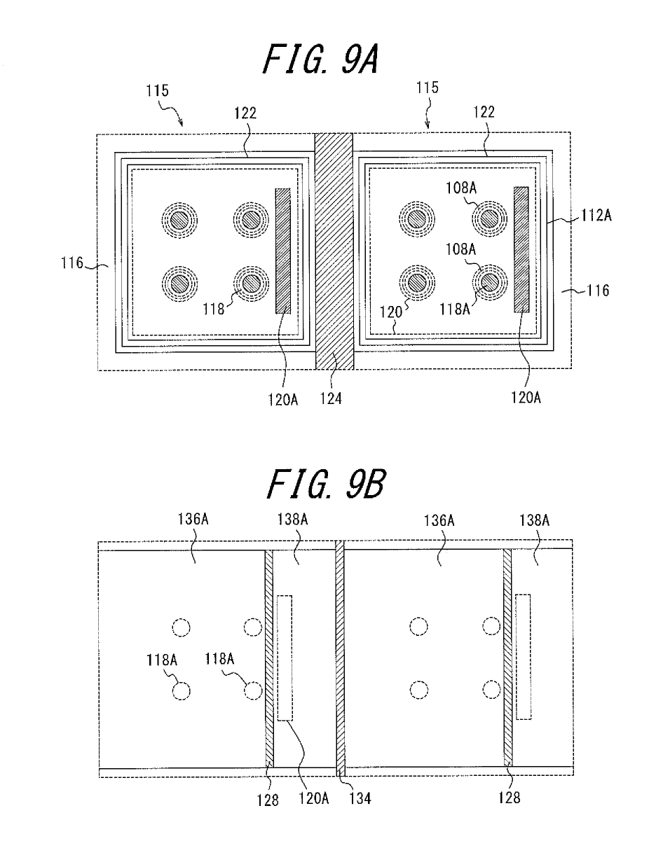

Described first is an example of a method of manufacturing a III nitride semiconductor device 100 in accordance with one embodiment of the present invention, where a chemical lift-off process is used, with reference to FIGS. 1(A) to 9(B). Now, the correspondence between the cross-sectional views of FIG. 1 to FIG. 7 and the top views of FIGS. 8 and 9 is described first. FIG. 8(A) is a top view corresponding to FIG. 1(B), and the cross section along line I-I in FIG. 8(A) corresponds to FIG. 1(B). Note that the other cross-sectional views are also taken along the same line as FIG. 1(B). FIG. 8(B) is a top view corresponding to FIG. 2(A). FIG. 9(A) is a top view corresponding to FIG. 2(B). FIG. 9(B) is a top view corresponding to FIG. 3(B).

First, a lift-off layer 104 is formed on a growth substrate 102 as shown in FIG. 1(A). An i-type III nitride semiconductor layer 106 (hereinafter referred to as “i-layer”) is formed as a buffer layer on the lift-off layer 104 and an n-type III nitride semiconductor layer 108 (hereinafter referred to as “n-layer”) having a first conductivity type is formed active layer 110, and p-type III nitride semiconductor layer 112 (hereinafter referred to as “p-layer”) having a second conductivity-type are then formed sequentially. This is the first step. Note that the i-type III nitride semiconductor layer refers to a layer that is not intentionally doped with any specific impurities (undoped layer). Ideally, a semiconductor completely free of impurities is preferred, yet a semiconductor that does not work as a p-type or n-type electrical conductor may be used, and one having low carrier concentration (for example, less than 5×10¹⁶/cm³) can be referred to as i-type semiconductor.

Next, as shown in FIG. 1(B) and FIG. 8(A), the p-layer 112, the active layer 110, the n-layer 108, and the i-layer 106 are partly removed to form grooves 116 in a grid pattern such that the growth substrate 102 is partly exposed at the bottom, thereby forming a plurality of semiconductor structures 114 each having a square transverse cross sectional shape, which are arranged longitudinally and laterally and include the n-layer 108, the active layer 110, and the p-layer 112. The structures formed on the growth substrate 102 and segmented by the grooves 116 are hereinafter referred to as device units 115. The device units 115 eventually constitute the respective III nitride semiconductor devices. Further, the combination of the growth substrate 102 and all the structures formed thereon are referred to as “wafer”.

The second step is then performed in which the p-layer 112 and the active layer 110 in each of the device units 115 are partly removed to partly expose the n-layer 108 as shown in FIG. 1(B) and FIG. 8(A). In this embodiment, exposed portions 108A of the n-layer are circular and formed at four portions in each of the semiconductor structures 114. However, considering the length through which the current flows (current spreading length) depending on the layer composition of the semiconductor structures 114, and the chip size, the positions where the exposed portions are arranged and the number of the exposed portions to be arranged can be determined as appropriate.

Next, the third step is performed in which for the device units 115, circular n-side contact layers 118 as first contact layers are formed on the respective exposed portions 108A of the n-layer, and p-side contact layers 120 as second contact layers are formed on substantially the entire surface of the p-layer 112 as shown in FIG. 2(A) and FIG. 8(B).

Next, the fourth step is performed in which for the device units 115, an insulating layer 122 is formed as shown in FIG. 2(B) and FIG. 9(A). The insulating layer 122 is formed on the exposed surface of the device units 115, specifically the exposed area of the semiconductor structures 114, on the n-side contact layers 118, and on the p-side contact layers 120. However, as shown in those diagrams, the insulating layer 122 is not formed on part of the n-side contact layers 118 and part of the p-side contact layers 120 to expose them. In this embodiment, the exposed portion 118A of each n-side contact layer is circular at the center of the n-side contact layer 118, whereas the exposed portion 120A of the p-type contact layer linearly extends between an end portions 112A of each remaining p-layer 112 and the exposed portions 108A of the n-layer that are closest to the end portions 112A in the top view (FIG. 9(A)). In FIG. 9(A), areas where the exposed portions 108A of the n-layer, the n-side contact layer 118, and the p-side contact layer 120 are covered with the insulating layer 122 are shown by broken lines. Note that the shape of the exposed portions 108A for the formation of the n-side contact layer is not necessarily circular, but can be concentric, interdigitated, or the like.

The grooves 116 in a grid pattern are then alternately filled up with a first resin 124 in the longitudinal direction as shown in FIG. 2(B) and FIG. 9(A). Thus, only one side of each device unit 115 is covered with the first resin 124. Note that the first resin 124 is removed in a subsequent step.

Next, a plating seed layer 126 is formed on substantially the whole exposed top surface of the wafer as shown in FIG. 3(A). On that occasion, in each of the device units 115, the plating seed layer 126 is not formed in a line almost parallel to the exposed 120A of the p contact layer on the insulating layer 122 between the exposed portion 120A of the p-side contact layer and the exposed portions 118A of the n-side contact layer, so that the insulating layer 122 is partly exposed.

The fifth step is then formed, in which in each of the device units 115, a first structure 128 made of an insulator is formed on part of the insulating layer 122 across the exposed surface of the device unit 115, specifically, so as to cover an exposed portion of the insulating layer 122 where the plating seed layer 126 is not formed as shown in FIG. 3(A). The exposed surface of each of the device units 115 is partitioned by the first structure 128 into a first exposed surface 130 including the exposed portions 118A of the n-side contact layers and a second exposed surface 132 including the exposed portion 120A of the p-side contact layer. Note that the first and second exposed surfaces 130 and 132 are defined as exposed surfaces excluding the plating seed layer 126. In FIG. 3(A), in each of the device units 115, the first exposed surface 130 is on the left side of the first structure 128, and the second exposed surface 132 is on the right side thereof.

A second resin 134 is then formed like the first structure 128 on the first resin 124 with the plating seed layer 126 therebetween, as shown in FIG. 3(A). The second resin 134 is also removed in a subsequent step.

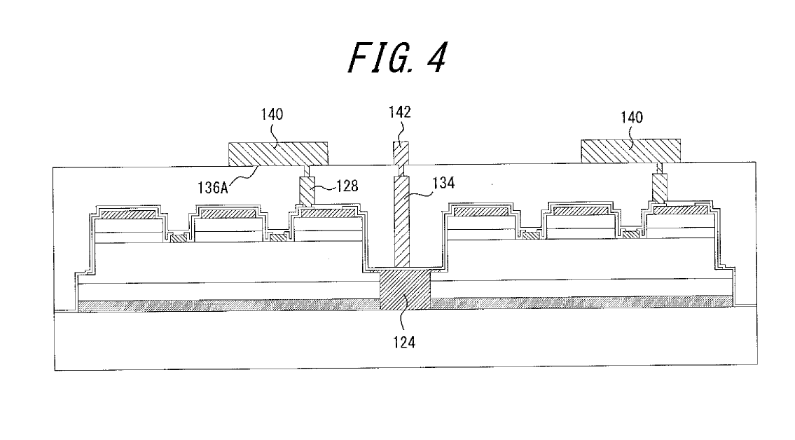

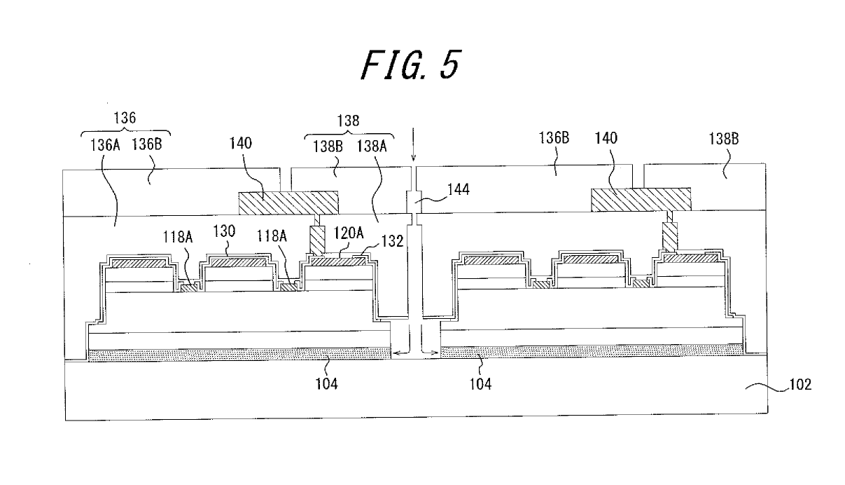

Next, the sixth step is performed in which plating layers are grown from the respective first and second exposed surfaces 130 and 132. In this embodiment, the sixth step includes the first plating step shown in FIG. 3(B) and FIG. 9(B), a second structure formation step shown in FIG. 4, and the second plating step shown in FIG. 5.

First, in the first plating step, as shown in FIG. 3(B) and FIG. 9(B), a first layer 136A of a first support is formed on the first exposed surface 130, whereas a first layer 138A of a second support is grown by plating on the second exposed surface 132. The plating growth is terminated in a stage where the first layers 136A and 138A do not join. As shown in FIG. 9(B), the first layer 136A of the first support is in contact with the exposed portions 118A of the n-side contact layers (broken lines in the diagram), whereas the first layer 138A of the second support is in contact with the exposed portions 120A of the p-side contact layers (broken lines in the diagram). The first structure 128 is located between the first layers 136A and 138A of the first and second supports.

Subsequently, as shown in FIG. 4, a second structure 140 made of an insulator and coupled to the first structure 128 is formed on the first layer 136A of the first support. In this embodiment, the second structure 140 is formed in a line having a longer width than the first structure 128. In addition, a third resin 142 coupled to the second resin 134 is formed on the second resin 134.

Subsequently, in the second plating step, as shown in FIG. 5, a second layer 136B of the first support and a second layer 138B of the second support are grown further by plating from the first layer 136A of the first support and the first layer 138A of the second support that are exposed, respectively. The plating growth is terminated in a stage where the second layers 136B and 138B do not join. The second structure 140 is located between the second layers 136B and 138B of the first and second supports.

Thus, a first support 136 can be formed on the first exposed surface 130 so as to be connected to the exposed portions 118A of the n-side contact layers to serve as an n-side electrode which is a first electrode, whereas a second support 138 can be formed on the second exposed surface 132 so as to be connected to the exposed portions 120A of the second contact layers to serve as a p-side electrode which is a second electrode. On this occasion, as shown in FIG. 5, due to the position of the second structure 140, after the first plating step, the top surface area of the second layer 138B of the second support is larger than that of the first layer 138A of the second support.

As shown in FIG. 5, the first resin 124, the second resin 134, and the third resin 142 are then removed, thereby forming a gap 144 communicated to the growth substrate 102 and the lift-off layer 104 of each device unit 115.

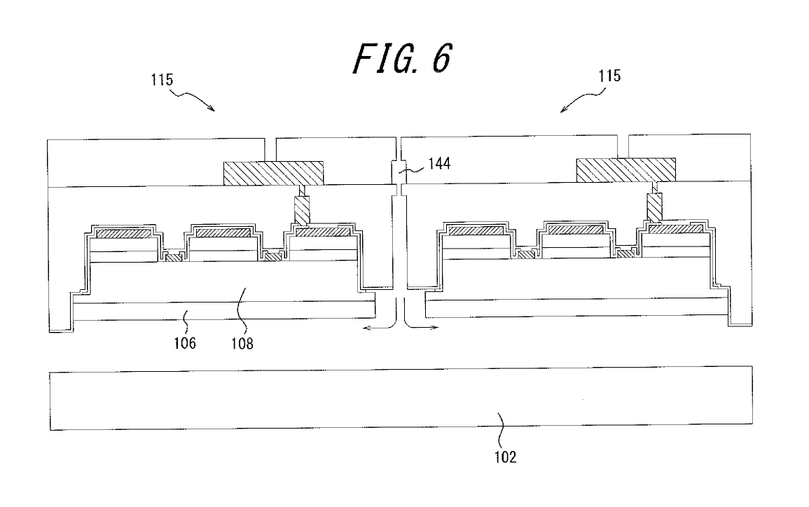

Next, the seventh step is performed in which an etchant is supplied to the gap 144 to remove the lift-off layer 104 by a chemical lift-off process, thereby separating the growth substrate 102 form the device units 115 as shown in FIG. 6. In this embodiment, each of the device units 115 has four sides, only one of which is constituted by the 144. Accordingly, the removal of the lift-off layer 104 progresses in one direction (directions shown by the arrow in FIG. 6) from the side constituted by the gap 144. Alternatively, a method of separating the growth substrate 102 from the device units 115 by a laser lift-off process may be used.

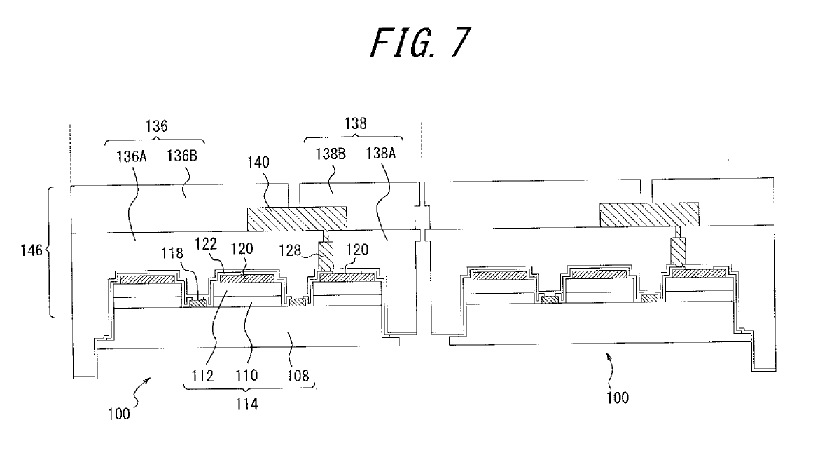

Finally, as shown in FIG. 7, the surface of the i-layer 106, which has been exposed by the removal of the lift-off layer 104 is further etched to expose the n-layer 108. Further, the first support 136 and the second support 138 are cut to singulate the device units 115. The cutting is performed along the broken lines in FIG. 7.

Thus, A plurality of III nitride semiconductor devices 100 can be fabricated in which the semiconductor structures 114 are supported by support bodies 146 including the first and second supports 136 and 138, and the first and second structures 128 and 140.

According to the manufacturing method of this embodiment, the support bodies 146 are not provided by bonding using bumps, but by plating growth, so that the growth substrate is not required to be aligned with respect to the support body and misalignment is not caused. Therefore, III nitride semiconductor devices can be fabricated by higher yield than the conventional methods.

### (III Nitride Semiconductor Device 100)

III nitride semiconductor devices 100 will be described with reference to FIG. 7. The III nitride semiconductor devices 100 each include a semiconductor structure 114 having an n-layer 108, an active layer 110, and a p-layer 112 in this layer. An n-side contact layer 118 is formed on the n-layer 108 at the bottom of recessed portions penetrating the p-layer 112 and the active layer 110. Further, a p-side contact layer 120 is provided on the p-layer 112. An insulating layer 122 for insulation between the n-side contact layers 118 and the p-side contact layers 120 is provided on part of the n-side contact layers 118, part of the p-side contact layers 120, and the semiconductor structure 114 situated between the n-side contact layers 118 and the p-side contact layers 120. On the insulating layer 122, a single first support 136, a single second support 138, and structures 128 and 140 made of an insulator and located between the adjacent first and second supports 136 and 138 are provided. The first support 136 is partly in contact with the n-side contact layers 118 to serve as an n-side electrode. The second support 138 is partly in contact with the p-side contact layer 120 to serve as a p-side electrode. The first and second supports 136 and 138, and the structures 128 and 140 serve as a support body 146 for supporting the semiconductor structure 114.

In accordance with the III nitride semiconductor device 100 of this embodiment, since under-filling having low heat dissipation performance is not used, and the first and second supports 136 and 138 having high heat dissipation performance, which are grown by plating constitute the main support body, good heat dissipation is achieved and the junction temperature can be lowered. Therefore, the III nitride semiconductor device can be operated at a higher current.

In the III nitride semiconductor device 100 of this embodiment, the semiconductor structure 114 has recessed portions at a plurality of positions and n-side contact layers 118 at a plurality of positions. This allows current to be flown uniformly in the device, which leads to improved device characteristics (light output power in the case of LEDs). The arrangement of the n-side contact layers is not limited to that in FIG. 9(A). For example, it is also preferable that the n-side contact layers have a circular shape with a diameter of 20 μm to 40 μm and they are provided at 16 positions in total at intersections of a 4×4 orthogonal grid at regular intervals. Alternatively, they may be arranged to be offset to the peripheral side of a chip in order to unify the current density, or may be arranged in a hexagonal close arrangement.

Further, the first and second supports 136 and 138 include first layers 136A and 138A provided on the insulating layer 122, and second layers 136B and 138B provided on the first layers 136A and 138A, respectively. The structures 128 and 140 include the first structure 128 positioned between the first layers 136A and 138A of the first and second supports, and the second structure 140 coupled to the first structure 128 and situated between the second layers 136B and 138B of the first and second supports.

Here, the top surface area of the second layer 138B of the second support is larger than that of the first layer 138A of the second support. This structure can be fabricated by the two-stage plating described above. When a plurality of n-side contact layers 118 are provided, the first layer 138A of the second support cannot be prevented from being significantly small as compared with the first layer 136A of the first support. However, using the two-stage plating, the top surface area of the second layer 138B of the second support can be made larger than that of the first layer 138A of the second support. In this case, when the III nitride semiconductor devices 100 are mounted on a separate package substrate or printed wiring board, etc., the alignment can be easily achieved.

Preferred embodiments for the steps in the method of manufacturing a III nitride semiconductor device 100 will now be described.

### (First Step)

For the growth substrate 102, it is preferable to use a sapphire substrate or an MN template substrate in which an AIN film is formed on a sapphire substrate. In the case of using a chemical lift-off process, the substrate can be selected as appropriate depending on the kind of the lift-off layer to be formed, the composition of Al, Ga, and In of a III nitride semiconductor layer, the quality of LED chips, the cost, and the like.

In the case of using a chemical lift-off process, the lift-off layer 104 is preferably a buffer layer made of a metal other than Group III metals or a nitride thereof, such as CrN, since it can be dissolved by selective chemical etching. The lift-off layer is preferably formed by sputtering, vacuum deposition, ion plating, or MOCVD. Typically, the thickness of the lift-off layer 104 is 2 nm to 100 nm.

The i-layer 106, n-layer 108, active layer 110, and the p-layer 112 are made of any given III nitride semiconductor such as GaN or AlGaN. If the active layer 110 is as a light emitting layer having a multiple quantum well (MQW) structure using a III nitride semiconductor, LEDs are obtained. If the active layer 110 is not a light emitting layer, other types of semiconductor devices are obtained. These layers can be epitaxially grown on the lift-off layer 104, for example by MOCVD. The first conductivity type is n-type and the second conductivity-type is p-type in this embodiment; however, naturally, the opposite combination may be used.

The grooves 116 are preferably formed by dry etching. This is because the termination of the etching on the III nitride semiconductor layers can be reproducibly controlled. In the present invention, the transverse cross sectional shape of the semiconductor structures 114 is not limited in particular as long as it is approximately quadrangular; however, it is preferably rectangular in terms of the effective area. The approximately quadrangular shape includes, for example, a quadrangle having rounded or chamfered corners other than a quadrangle. Further, the transverse cross sectional shape may be a shape based on an oblong having long and short sides with different lengths or a polygon such as a hexagon.

The semiconductor structures 114 each has a side of generally 250 μm to 3000 μm. Further, the maximum width of the grooves 116 is preferably in the rage of 40 μm to 200 μm, more preferably in the range of 60 μm to 100 μm. The width of 40 μm or more allows the etchant to be supplied to the grooves 116 smoothly enough, whereas the width of 200 μm or less allows the loss of light emitting area to be minimized.

### (Second Step)

The second step for partly removing the p-layer 112 and active layer 110 to partly expose the n-layer 108 is preferably performed by dry etching using resist as a mask. This allows the termination of the etching on the n-layer 108 to be reproducibly controlled.

### (Third Step)

The n-side contact layer 118 can be formed by a lift-off process using resist as a mask. For the electrode material, Al, Cr, Ti, Ni, Ag, Au, etc. is used.

The p-side contact layer 120 can be formed by a lift-off process using resist as a mask. For the electrode material, Ni, Ag, Ti, Pd, Cu, Au, Rh, Ru, Pt, Ir, etc. is used.

### (Fourth Step)

The insulating film 122 is made of for example, SiO₂, SiN, or the like, and after it is formed to 0.5 μm to 2.0 μm by PECVD, resist patterns are formed as masks by wet etching or dry etching.

The first resin 124 can be formed by a given patterning technique by applying a given resist material. This also applies to the second resin 134 and the third resin 142.

### (Fifth Step)

The first structure 128 and the second structure 140 are made of a material different from the above described material of the first resin 124, and they constitute part of a device as support bodies. For such an insulating material, for example, a resin such as epoxy resin or polyimide, or an inorganic material such as SiO₂ or SiN can be used. Those structures may be formed by a given patterning technique; however, photoresist for permanent films (SU-8, for example) used for example in microelectromechanical systems (MEMS) can simplify the process. Desirably, the height of the first structure 128 and the second structure 140 is 10 μm to 100 μm, and the width thereof is 10 μm to 100 μm, and 500 μm to 900 μm, respectively.

### (Sixth Step)

The first support 136 and the second support 138 can be formed by plating such as wet plating or dry plating. For example, Cu or Au electroplating is employed; Cu, Ni, Au, or the like can be used for a surface of a plating seed layer 126 (on the conductive support side). In this case, for the growth substrate side (the semiconductor structures side) of the plating seed layer 126, a metal having sufficient adhesion with the semiconductor structures 114 and the insulating film 122, for example, Ti or Ni is preferably used. The plating seed layer 126 can be formed for example by sputtering. The thickness of the plating seed layer 126 can be 2.0 μm to 20 μm, whereas the thickness of the first support 136 and the second support 138 can be approximately 10 μm to 200 μm.

### (Seventh Step)

The first resin 124, the second resin 134, and the third resin 142 can be removed using for example, a solution that dissolves a resin such as acetone and alcohols. On that occasion, the plating seed layer 126 between the first resin 124 and the second resin 134 is not dissolved by acetone or the like; however, since the plating seed layer 126 is an extremely thin film as compared with the first resin 124 and the second resin 134, it can be easily removed. The plating seed layer 126 can be removed mechanically or may be removed by metal etching or the like. On that occasion, the first structure 128 and the second structure 140 are ensured not to be removed.

The removal of the lift-off layer 104 is performed by a typical chemical lift-off process or a photochemical lift-off process. A chemical lift-off process is a method of etching a lift-off layer. In particular, a method for etching a lift-off layer while activating it by irradiation with light such as ultraviolet light is called a photochemical lift-off process. Examples of etchants that can be used include a diammonium cerium nitrate solution or a potassium ferricyanide-based solution when the lift-off layer is made of CrN. Whereas when the lift-off layer is made of ScN, examples of the etchants include known etchants having selectivity, such as hydrochloric acid, nitric acid, and organic acid. Alternatively, the growth substrate can be removed by a laser lift-off process or a method for removing the growth substrate itself by dissolution or mechanical polishing.

The surface of the i-layer 106, which has been exposed by the removal of the lift-off layer 104 is preferably cleaned by wet cleaning. Subsequently, dry etching and/or wet etching may be performed to a given extent to expose the n-layer 108. In the III nitride semiconductor device 100 of the present invention, both the n-side electrode and the p-side electrode are provided on the support body 146 side, so that etching on the surface exposed by removing the lift-off layer 104 is optional. When the device 100 is an LED, the exposed surface serves as a light extraction surface. Therefore, preferably the surface is subjected to wet etching for the formation of irregularities and is covered with a protective film of SiO₂ or the like in order to ensure reliability in moisture resistance or the like.

The first support 136 and the second support 138 can be cut using for example a blade dicer or a laser dicer.

The above shows examples of typical embodiments, and the present invention is not limited to those embodiments. Accordingly, suitable modifications can be made to the present invention unless departing from the scope of the claims.

### EXAMPLES

### Example 1

Steps of FIG. 1(A) to FIG. 3(B) were performed and without performing two-stage plating after that, LED chips were fabricated by a chemical lift-off process. Specifically, first, as shown in FIG. 1(A), a Cr layer was formed on a sapphire substrate by sputtering and heat treatment was performed in an atmosphere containing ammonia to form a lift-off layer (CrN layer, thickness: 18 nm), and an i-type GaN layer (thickness: 4 μm), an n-type GaN layer (thickness: 6 μm), a light emitting layer (AlInGaN based MQW layer, thickness: 0.1 μm), and a p-type GaN layer (thickness: 0.2 μm) were epitaxially grown sequentially by MOCVD.

Subsequently, as shown in FIG. 1(B) and FIG. 8(A), the p-type GaN layer, the light emitting layer, the n-type GaN layer, and the i-type GaN layer were partly removed by dry etching to form grooves in grid pattern, forming a plurality of semiconductor structures each having a square transverse cross sectional shape, arranged longitudinally and laterally. The semiconductor structures had a side length of 1500 μm, whereas the grooves had a maximum width of 100 μm.

Further, the p-type GaN layer and the light emitting layer were partly removed by ICP-RIE dry etching using resist as a mask to partly expose the n-type GaN layer. Exposed portions of the n-type GaN layer are arranged at four positions in each device in FIG. 8(A), however, they were arranged at 16 positions in this example and had a diameter of 60 μm.

Next, as shown in FIG. 2(A) and FIG. 8(B), after resist was prepared as a mask, circular n-side contact layers (material: Cr/Ni/Ag, thickness: 50 nm/20 nm/400 nm) were formed on the exposed portions of the n-type GaN layer by EB deposition, and the resist was removed. Further, after preparing resist as a mask, p-side contact layer (material: Ni/Ag/Ni/Ti, thickness: 5 angstroms/200 nm/25 angstroms/25 angstroms) was formed over substantially whole surface of the p-type GaN layer by EB deposition, and the resist was removed.

Next, as shown in FIG. 2(B) and FIG. 9(A), after an insulating layer (SiO₂, thickness: 0.7 μm) was formed on substantially the whole surface by PECVD, the insulating layer was partly wet etched by BHF using resist as a mask, thereby exposing part of the n-side contact layers and part of the p-side contact layer. The exposed portions of the n-side contact layers had a diameter of 30 μm, and the exposed portion of the p-side contact layer had a width of 60 μm. Further, the grooves in a grid pattern were alternately filled up with photoresist (width: 100 μm, height: 10 μm) in the longitudinal direction using photolithography.

Next, as shown in FIG. 3(A), a plating seed layer (Ti/Ni/Au, thickness: 0.02 μm/0.2 μm/0.6 μm) was formed on substantially the whole surface of the exposed surface on the top surface side of the wafer by sputtering. Using resist as a mask, the insulating layer of only the position shown in FIG. 3(A) was exposed. The width of the insulating layer was 50 μm. Thus, the plating seed layer was partitioned into a region a where a first support to be described would be formed and a region where the second support would be formed, thus electrically separating the regions.

Further, a first structure (width: 100 μm, height: 30 μm) made of SU-8 was formed to cover the exposed portion of the insulating layer using photolithography. In a similar manner, photoresist (width: 550 μm, height: 30 μm) was additionally formed to the same height as the first structure using photolithography on the photoresist formed on the alternate grooves.

Next, as shown in FIG. 3(B) and FIG. 9(B), Cu was formed from the plating seed layer by plating to form first layers (thickness on p-type GaN layer: 40 μm) of the first and second supports. The plating was electroplating using a copper sulfate-based electrolyte solution, where the temperature of the solution was in the range of 25° C. to 30° C., and the deposition rate was 35 mm/hr. The widths of the first layers of the first and second supports were 1200 μm and 150 μm, respectively. The first support and the second support were electricity separated by the first structure.

After that, only the photoresist provided in the grooves was removed using acetone to form a gap communicated to the sapphire substrate and the lift-off layer.

A selective etchant for the lift-off layer was supplied to the gap and the lift-off layer was removed by a chemical lift-off process, thereby separating the sapphire substrate from the device units.

After that, the i-type GaN layer exposed by the removal of the lift-off layer was dry etched using an ICP-RIE apparatus. Finally, the first support and second support were cut using a laser dicer, thereby obtaining 600 LED chips according to Example 1.

### Example 2

LED chips shown in FIG. 7 were fabricated by a manufacturing method using two-stage etching shown in FIGS. 1(A) to 7. The steps up to FIG. 3(B) and FIG. 9(B) are the same as those in Example 1, so the description will be omitted.

After those steps, as shown in FIG. 4, a second structure (width: 550 μm, height: 30 μm) made of SU-8 and coupled to the first structure was formed on the first layer of the first support using photolithography. In a similar manner, photoresist (width: 80 μm, height: 25 μm) was additionally formed using photolithography above the photoresist formed on the alternate grooves.

Next, as shown in FIG. 5, Cu is further formed from the first layers of the first support and second support by plating, thereby forming second layers (thickness on first layer: 200 μm) of the first and second supports. The plating was electroplating using a copper sulfate-based electrolyte solution, where the temperature of the solution was in the range of 25° C. to 30° C., and the deposition rate was 35 mm/hr. The widths of the second layers of the first and second supports were 930 μm and 310 μm, respectively. Thus, by two-stage plating, the top surface area of the second layer of the second support after the first plating step was made larger than that of the first layer of the second support.

The steps following the removal of the lift-off layer are the same as those in Example 1, so the description will be omitted. Thus, 600 LED chips according to Example 2 were obtained.

### Comparative Example

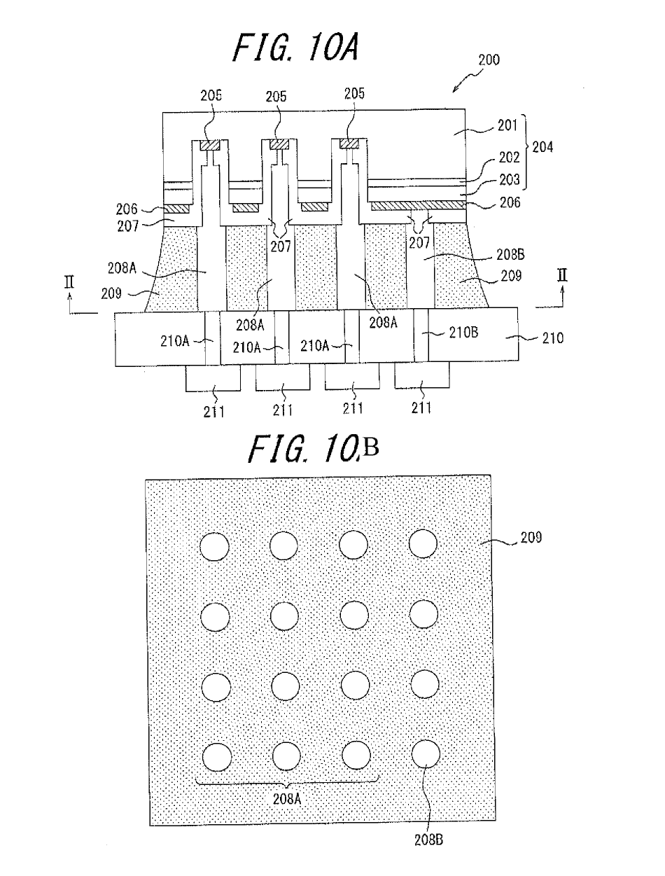

LED chips shown in FIGS. 10(A) and 10(B) were fabricated in the same manner as Example except that the bonding to the submount substrate was performed using Au bumps by the method described in the background art instead of using a plating seed layer and a plating process, thereby obtaining 600 chips. As different from Examples, exposed portions of the n-side contact layers and the p-side contact layers are arranged as shown in FIG. 10(A). As shown in FIG. 10(B), the number of the Au bumps 208A connected to the n-side contact layers was 4×3:12 in total, whereas the number of Au bumps 208A connected to the p-side contact layers was 4×1:4 in total, and the bumps each had a diameter of 60 μm. Epoxy resin was used as the under-filling to fill between the Au bumps. A submount substrate having an alumina ceramics substrate as a main body provided with wires connected to the Au bumps was used as the support body.

### <Evaluation of Yield>

For the 600 devices of each of Examples 1 and 2 and Comparative Example, the non-defective rate obtained by performing a energizing test and an appearance test using a sorting machine is defined as a yield. As a result, the yield was 90% in Example 1, 90% in Example 2, and 50% in Comparative Example. Moreover, when a mounting step of soldering using an Au—Sn solder at 300° C. was performed to supply current to the first support and the second support, the yield in the mounting step of Example 2 improved by 10% as compared with Example 1.

### <Evaluation of Heat Dissipation Performance>

A T3ster system was used to measure the thermal resistance (Rth) of the devices of Examples 1, 2, and Comparative Example at 25° C. As a result, the Rth was approximately 3.8K/W in Examples 1 and 2, and the Rth was approximately 8.2K/W in Comparative Example.

Thus, LEDs having higher dissipation performance were fabricated at higher yield in Examples 1 and 2 as compared with Comparative Example.

### INDUSTRIAL APPLICABILITY

The present invention can provide a III nitride semiconductor device having higher heat dissipation performance, and a method of manufacturing a III nitride semiconductor device, which makes it possible to fabricate such a III nitride semiconductor device at higher yield.

### REFERENCE SIGNS LIST

100: III nitride semiconductor device
102: Growth substrate
104: Lift-off layer
106: i-type III nitride semiconductor layer
108: n-type III nitride semiconductor layer
108A: Exposed portion of n-type III nitride semiconductor layer
110: Active layer
112: p-type III nitride semiconductor layer
114: Semiconductor structure
115: Device unit
116: Groove
118: n-side contact layer (first contact layer)
118A: Exposed portion of n-side contact layer
120: p-side contact layer (second contact layer)
120A: Exposed portion of p-side contact layer
122: Insulating layer
124: First resin
126: Plating seed layer
128: First structure
130: First exposed surface
132: Second exposed surface
134: Second resin
136: First support (n-side electrode)
136A: First layer of first support
136B: Second layer of first support
138: Second support (p-side electrode)
138A: First layer of second support
138B: Second layer of second support
140: Second structure
142: Third resin
144: Gap
146: Support body

1. A method of manufacturing a III nitride semiconductor device, comprising:
a first step of forming semiconductor structures obtained by sequentially stacking a first conductivity type III nitride semiconductor layer, an active layer, and a second conductivity type III nitride semiconductor layer on a growth substrate;
a second step of partly exposing the first conductivity type III nitride semiconductor layer by partly removing the second conductivity-type III nitride semiconductor layer and the active layer;
a third step of forming first contact layers on exposed portions of the first conductivity type III nitride semiconductor layer and forming second contact layers on exposed portions of the second conductivity type III nitride semiconductor layer;
a fourth step of forming an insulating layer on the semiconductor structures, the first contact layers, and the second contact layers that are exposed, with part of the first contact layers and part of the second contact layers being exposed;
a fifth step of forming a first structure made of an insulator on part of the insulating layer across an exposed surface, thereby partitioning the exposed surface into a first exposed surface having the exposed portions of the first contact layers and a second exposed surface having the exposed portion of the second contact layer, by the first structure;
a sixth step of growing plating layers from the respective first and second exposed surfaces, thereby forming a first support serving as a first electrode in contact with the exposed portions of the first contact layers on the first exposed surface, and forming a second support serving as a second electrode in contact with the exposed portion of the second contact layer on the second exposed surface; and
a seventh step of separating the growth substrate using a lift-off process, whereby a III nitride semiconductor device having the semiconductor structures supported by a support body including the first and second supports and the first structure is fabricated.

2. The method of manufacturing a III nitride semiconductor device, according to claim 1, wherein in the second step, the exposed portions of the first conductivity type III nitride semiconductor layer are formed at a plurality of positions in the semiconductor structure, and in the third step, the first contact layers are formed at a plurality of positions.

3. The method of manufacturing a III nitride semiconductor device, according to claim 2, wherein the sixth step comprises:
a first plating step for forming a first layer of the first support on the first exposed surface and growing a first layer of the second support on the second exposed surface by plating;
a step of forming a second structure made of an insulator and coupled to the first structure, on the first layer of the first support; and
a second plating step for growing from the first layer of the first support and the first layer of the second support that are exposed, a second layer of the first support and a second layer of the second support, respectively by plating, wherein the top surface area of the first layer of the second support after the first plating step is larger than that of the second layer of the second support.

4. A III nitride semiconductor device comprising:
semiconductor structures each having a first conductivity type III nitride semiconductor layer, an active layer, and a second conductivity type III nitride semiconductor layer in this order;
a first contact layer provided on the first conductivity type III nitride semiconductor layer at the bottom of a recessed portion penetrating the second conductivity-type III nitride semiconductor layer and the active layer;
a second contact layer provided on the second conductivity type III nitride semiconductor layer;
an insulating layer for insulation between the first contact layer and the second contact layer, provided on part of the first contact layer, part of the second contact layer, and the semiconductor structure situated between the first contact layer and the second contact layer and;
a single first support partly in contact with the first contact layer to serve as a first electrode, a single second support partly in contact with the second contact layer to serve as a second electrode, and a structure made of an insulator located between the adjacent first and second supports on the insulating layer, wherein the first and second supports and the structure constitute a support body for supporting the semiconductor structure.

5. The III nitride semiconductor device, according to claim 4, wherein the semiconductor structure has recessed portions at a plurality of positions, and the first contact layer is provided at a plurality of positions.

6. The III nitride semiconductor device, according to claim 5, wherein the first and second supports each include a first layer provided on the insulating layer and a second layer provided on the first layer,
the structure includes a first structure situated between the first layers of the first and second supports, and a second structure coupled to the first structure and situated between the second layers of the first and second supports, and
the top surface area of the second layer of the second support is larger than that of the first layer of the second support.
